(19) United States
(12) Patent Application Publication
(10) Pub. No.: US 2026/0366742 A1
(43) Pub. Date: Nov. 19, 2026

(54) AIR CONDITIONER

(71) Applicant: GD MIDEA AIR-CONDITIONING EQUIPMENT CO., LTD., Foshan (CN)

(72) Inventors: Shengchang HU, Foshan (CN); Junhua ZHOU, Foshan (CN); Fashen LIU, Foshan (CN); Shun ZHAO, Foshan (CN)

(21) Appl. No.: 19/133,856

(22) PCT Filed: Aug. 18, 2023
(86) PCT No.: PCT/CN2023/113825

§ 371 Date: May 29, 2025

(30) Foreign Application Priority Data
Dec. 5, 2022 (CN) 202211552219.3

(51) Int. Cl. F24F 1/24; F24F 1/031

(52) U.S. Cl. CPC F24F 1/24; F24F 1/031

(57) ABSTRACT

The present application is related to an air conditioner, comprising an electrical control box, an enclosing panel, a water baffle and a fan. The electrical control box is connected to the enclosing panel, electrical control box heat dissipation holes being provided at the electrical control box, and enclosing panel heat dissipation holes being provided at the enclosing panel. The water baffle is arranged on the side of the enclosing panel facing away from the electrical control box and corresponding to the positions of the enclosing panel heat dissipation holes, and a heat dissipation channel is formed between the water baffle and the enclosing panel. The fan is arranged on the side of the enclosing panel facing away from the electrical control box, and a heat dissipation area is formed between the side of the fan facing the enclosing panel and the enclosing panel. A heat dissipation port of the heat dissipation channel communicates with the heat dissipation area.

This application claims priority to the Chinese Patent Application 202211552219.3 filed with the China National Intellectual Property Administration on Dec. 5, 2022 and entitled “AIR CONDITIONER,” the disclosure of which is incorporated herein by reference in its entirety.

### FIELD

The present disclosure relates to the field of air conditioning technology, and in particular to an air conditioner.

### BACKGROUND

The electrical control box of existing window air conditioners is provided with a sealing structure for waterproofing. Meanwhile, in the internal design of the air conditioners, the electrical control box is generally not in direct contact with the outdoor environment. As such, the heat dissipation capacity of the electrical control box is limited.

In some engineering practices, DC (direct current) motors are used according to engineering requirements, in which case a large amount of heat will be rapidly generated inside the electrical control box, and the heat inside the electrical control box needs to be dissipated in time.

### SUMMARY

In order to solve or at least partially solve the above problems, an embodiment of the present disclosure provides an air conditioner.

An embodiment of the present disclosure provides an air conditioner, including: an electrical control box, an enclosing panel, a water baffle and a fan. The electrical control box is connected to the enclosing panel. The electrical control box is provided with electrical control box heat dissipation holes. The enclosing panel is provided with enclosing panel heat dissipation holes. The water baffle is arranged on a side of the enclosing panel away from the electrical control box and corresponds to the position of the enclosing panel heat dissipation holes. A heat dissipation channel is formed between the water baffle and the enclosing panel. The fan is arranged on the side of the enclosing panel away from the electrical control box. A heat dissipation area is formed between a side of the fan facing the enclosing panel and the enclosing panel, and a heat dissipation port of the heat dissipation channel is in communication with the heat dissipation area.

The air conditioner provided by the embodiment of the present disclosure includes the electrical control box, the enclosing panel, the water baffle and the fan. The electrical control box is connected to the enclosing panel. The electrical control box is provided with electrical control box heat dissipation holes, and the enclosing panel is provided with enclosing panel heat dissipation holes. With such configuration, the heat dissipated by the internal components of the electrical control box may be timely conducted out through the electrical control box heat dissipation holes and the enclosing panel heat dissipation holes. The water baffle is arranged on the side of the enclosing panel facing away from the electrical control box and corresponds to the position of the enclosing panel heat dissipation holes. Through the water blocking effect of the water baffle on the enclosing panel heat dissipation holes, it is ensured that outdoor rainwater or water droplets will not enter the electrical control box through the enclosing panel heat dissipation holes and the electrical control box heat dissipation holes, thereby avoiding the influence of rainwater or water droplets on the normal operation of the internal components of the electrical control box. The heat dissipation channel is formed between the water baffle and the enclosing panel. The fan is arranged on the side of the enclosing panel facing away from the electrical control box. The heat dissipation area is formed between the side of the fan facing the enclosing panel and the enclosing panel. When the fan is working, this heat dissipation area will become a negative pressure heat dissipation area. The negative pressure heat dissipation area may timely suck in hot air and dissipate it to the outside of the air conditioner through the fan. The water baffle is located on a side of the enclosing panel facing the fan. The heat dissipation port of the heat dissipation channel is located in the heat dissipation area. That is, the heat dissipated by the internal components of the electrical control box is conducted to the heat dissipation channel through the electrical control box heat dissipation holes and the enclosing panel heat dissipation holes, and then is sucked away by the negative pressure heat dissipation area formed by the operation of the fan and dissipated through the fan. That is to say, a structure that can both achieve heat dissipation and meet the waterproof requirements is provided for the electrical control box of the air conditioner, thereby meeting the performance requirements of the air conditioner under different working conditions and working scenarios.

In some embodiments, on a projection plane perpendicular to the enclosing panel, projections of the electrical control box heat dissipation holes are spaced apart from projections of the enclosing panel heat dissipation holes.

In some embodiments, the electrical control box includes an electrical control box body and an electrical control box cover. The enclosing panel includes a front enclosing panel and a lateral enclosing panel, which are connected to from an L-shape connection. The lateral enclosing panel is provided with an electrical control box accommodation opening for receiving the electrical control box body and a plurality of electrical control box mounting holes arranged around the electrical control box accommodation opening. Connection holes corresponding to the electrical control box mounting holes are arranged on the electrical control box body and/or the electrical control box cover.

In some embodiments, the electrical control box heat dissipation holes include first heat dissipation holes arranged on a side wall of the electrical control box body close to the front enclosing panel. The first heat dissipation holes are arranged in a staggered manner with respect to the enclosing panel heat dissipation holes. A gap is reserved between the electrical control box body and the front enclosing panel and connects the first heat dissipation holes to the enclosing panel heat dissipation holes, such that a first heat dissipation passage is formed. The first heat dissipation passage is in communication with the heat dissipation channel through the enclosing panel heat dissipation holes.

In some embodiments, the air conditioner includes an air duct volute located on a side of the front enclosing panel facing the electrical control box, where a gap is reserved between the electrical control box body and the air duct volute in a direction of a side of the electrical control box body away from the front enclosing panel and in a direction of a side of the electrical control box body away from the electrical control box cover to form a second heat dissipation passage.

The electrical control box heat dissipation holes further include second heat dissipation holes arranged on a side wall of the electrical control box body away from the front enclosing panel, the second heat dissipation holes are in communication with the enclosing panel heat dissipation holes through the second heat dissipation passage, and the enclosing panel heat dissipation holes are arranged directly opposite the second heat dissipation passage.

In some embodiments, a heat vent is arranged on a side of the electrical control box body away from the front enclosing panel, the heat vent is located at a lower part of the electrical control box body, and the second heat dissipation holes are located at an upper part of the electrical control box body.

In some embodiments, the air conditioner includes an air conditioner outer housing, where the electrical control box, the enclosing panel, the water baffle and the fan are all located inside the air conditioner outer housing. An air intake passage is formed between the air conditioner outer housing and the fan, and the water baffle is arranged directly opposite the air intake passage.

In some embodiments, the water baffle includes a water baffling member opposite the air intake passage and upper and lower connection members connected to the water baffling member at a predetermined angle, and the water baffle is connected to the front enclosing panel via the upper and lower connection members.

In some embodiments, a side surface of the water baffle close to the air conditioner outer housing is compressively sealed to the air conditioner outer housing through a flexible connection. A heat dissipation opening is arranged on a side of the water baffle close to the fan so that the heat dissipation channel is in communication with the heat dissipation area.

In some embodiments, the water baffling member is bent on a side close to the fan towards the front enclosing panel at a predetermined angle, the enclosing panel heat dissipation holes are arranged at an upper part of the front enclosing panel, the water baffling member narrows in a direction away from the fan at a position below a predetermined height of a lower edge of the enclosing panel heat dissipation holes.

In some embodiments, a gap is reserved between the air conditioner outer housing and the electrical control box cover to form a third heat dissipation passage. The third heat dissipation passage is in communication with the heat dissipation channel, the electrical control box heat dissipation holes further include third heat dissipation holes arranged on the electrical control box cover, and the third heat dissipation holes are in communication with the heat dissipation channel through the third heat dissipation passage.

In some embodiments, both the electrical control box heat dissipation holes and the enclosing panel heat dissipation holes are louvered heat dissipation holes. The electrical control box heat dissipation holes are inclined downward in a direction from an inner side of the electrical control box to an outer side of the electrical control box, and the enclosing panel heat dissipation holes are inclined downward in a direction from a side facing the electrical control box to a side away from the electrical control box of the enclosing panel.

In some embodiments, a cable passage hole is arranged on a side of the electrical control box body close to the front enclosing panel, a sealing rubber block is arranged at the cable passage hole, and a waterproof cable-pressing cover plate is arranged on the front enclosing panel at a position directly opposite the cable passage hole.

### BRIEF DESCRIPTION OF DRAWINGS

The accompanying drawings, which are incorporated into and constitute a part of the specification, illustrate embodiments consistent with the present disclosure and, together with the description, serve to explain the principles of the present disclosure.

In order to more clearly explain the embodiments of the present disclosure or the technical scheme in the related art, the drawings in the description of the embodiments or the related art will be briefly introduced below. Apparently, for those of ordinary skill in the art, other drawings can be derived on the basis of these drawings without any inventive effort.

FIG. 1 is a schematic diagram of a three-dimensional external structure of an air conditioner according to an embodiment of the present disclosure;

FIG. 2 is a schematic diagram of a three-dimensional structure of the air conditioner with a water baffle installed according to an embodiment of the present disclosure;

FIG. 3 is a schematic diagram of a three-dimensional structure of the air conditioner with the water baffle removed according to an embodiment of the present disclosure;

FIG. 4 is a schematic side view of a three-dimensional structure of the air conditioner with an electrical control box cover opened according to an embodiment of the present disclosure;

FIG. 5 is a schematic side view of a three-dimensional structure of the air conditioner with the electrical control box cover opened from another angle according to an embodiment of the present disclosure;

FIG. 6 is a schematic sectional diagram of the air conditioner according to an embodiment of the present disclosure;

FIG. 7 is an enlarged view of the structure at part A in FIG. 6.

### IN THE DRAWINGS

1. electrical control box; 11. electrical control box body; 12. electrical control box cover;
2. enclosing panel; 21. front enclosing panel; 211. waterproof cable-pressing cover plate; 22. lateral enclosing panel;
3. water baffle; 31. water baffling member; 32. upper and lower connection members;
4. fan; 41. air duct volute;
5. electrical control box heat dissipation hole; 51. first heat dissipation hole; 52. second heat dissipation hole; 53. third heat dissipation hole; 54. heat vent;
6. enclosing panel heat dissipation hole;
7. heat dissipation channel; 71. first heat dissipation passage; 72. second heat dissipation passage; 73. third heat dissipation passage;
8. air conditioner outer housing;
9. air intake passage;
10. cable passage hole; 101. sealing rubber block.

### DETAILED DESCRIPTION OF EMBODIMENTS

In order to make the objectives, technical schemes and advantages of embodiments of the present disclosure clearer, the technical schemes in the embodiments of the present disclosure are clearly and completely described hereinafter. It is obvious that the described embodiments are only some of the embodiments instead of all the embodiments of the present disclosure. All other embodiments obtained by those having ordinary skill in the art based on the embodiments of the present disclosure without inventive effort shall fall within the scope of the present disclosure.

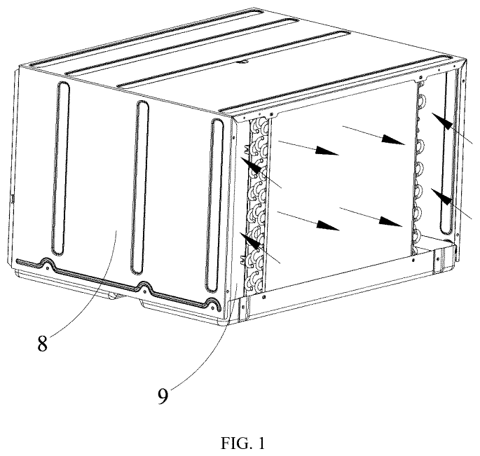

Referring to FIGS. 1 to 7, the present disclosure provides an air conditioner, including an electrical control box 1, an enclosing panel 2, a water baffle 3 and a fan 4. The electrical control box 1 is connected to the enclosing panel 2. The electrical control box 1 is provided with electrical control box heat dissipation holes 5. The enclosing panel 2 is provided with enclosing panel heat dissipation holes 6. The water baffle 3 is arranged on a side of the enclosing panel 2 away from the electrical control box 1 and corresponds to the position of the enclosing panel heat dissipation holes 6. A heat dissipation channel 7 is formed between the water baffle 3 and the enclosing panel 2. The fan 4 is arranged on the side of the enclosing panel 2 away from the electrical control box 1. A heat dissipation area is formed between a side of the fan 4 facing the enclosing panel 2 and the enclosing panel 2, and a heat dissipation port of the heat dissipation channel 7 is in communication with the heat dissipation area.

In some embodiments, the electrical control box 1 is connected to the enclosing panel 2. The electrical control box 1 is provided with the electrical control box heat dissipation holes 5. The electrical control box heat dissipation holes 5 are used to realize the air communication between the inside and the outside of the electrical control box 1, accelerate the heat exchange of air between inside and outside the electrical control box 1, so that the heat dissipated by the internal components of the electrical control box 1 may be timely conducted to the outside of the electrical control box 1 through the electrical control box heat dissipation holes 5. The enclosing panel 2 is provided with the enclosing panel heat dissipation holes 6. The enclosing panel heat dissipation holes 6 are used to realize the air communication between two sides of the enclosing panel heat dissipation holes 6, so that the heat conducted out by the electrical control box 1 may be further conducted out in time. The water baffle 3 is arranged on a side of the enclosing panel 2 facing away from the electrical control box 1 and corresponds to the position of the enclosing panel heat dissipation holes 6. In an embodiment, in a direction perpendicular to the enclosing panel 2, at least part of the water baffle 3 blocks the enclosing panel heat dissipation holes 6, thereby preventing outdoor rainwater or water droplets from passing through the enclosing panel heat dissipation holes 6. Through the water baffling effect of the water baffle 3 on the enclosing panel heat dissipation holes 6, it is ensured that outdoor rainwater or water droplets will not enter the electrical control box 1 through the enclosing panel heat dissipation holes 6 and the electrical control box heat dissipation holes 5, thereby avoiding the influence of rainwater or water droplets on the normal operation of the internal components of the electrical control box 1.

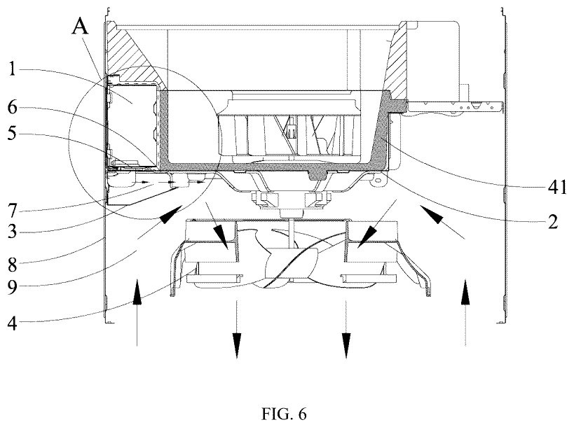

In some embodiments, the heat dissipation channel 7 is formed between the water baffle 3 and the enclosing panel 2. The fan 4 is arranged on the side of the enclosing panel 2 facing away from the electrical control box 1. The heat dissipation area is formed between the side of the fan 4 facing the enclosing panel 2 and the enclosing panel 2. When the fan 4 is working, this heat dissipation area will become a negative pressure heat dissipation area. Referring to the arrows shown near the fan in FIG. 6, which indicate the air flow direction when the fan is working, the negative pressure heat dissipation area formed by the operation of the fan 4 may timely suck in hot air and dissipate it to the outside of the air conditioner through the fan 4. The water baffle 3 is located on a side of the enclosing panel 2 facing the fan 4. The heat dissipation port of the heat dissipation channel 7 is in communication with the heat dissipation area. That is, the heat dissipated by the internal components of the electrical control box 1 is conducted to the heat dissipation channel 7 through the electrical control box heat dissipation holes 5 and the enclosing panel heat dissipation holes 6, and then is sucked away by the negative pressure heat dissipation area formed by the operation of the fan 4 and dissipated through the fan 4. That is to say, a structural design that can both achieve heat dissipation and meet the waterproof requirements is provided for the electrical control box 1, thereby meeting the performance requirements of the air conditioner under different working conditions and working scenarios.

The electrical control box in the present disclosure may also be other electrical components with heat dissipation and waterproof requirements. Moreover, the air conditioner in the present disclosure may be a window air conditioner, a wall-mounted air conditioner, or a floor-standing air conditioner, and as long as the air conditioner is internally equipped with electrical components with heat dissipation and waterproof requirements, the type and model of the air conditioner are not limited.

In some embodiments, on a projection plane perpendicular to the enclosing panel 2, projections of the electrical control box heat dissipation holes 5 are spaced apart from projections of the enclosing panel heat dissipation holes 6. That is to say, the electrical control box heat dissipation holes 5 and the enclosing panel heat dissipation holes 6 are arranged in a staggered manner. In this way, even if rainwater or water droplets enter the area of the electrical control box 1 through the enclosing panel heat dissipation holes 6, they will not directly enter the electrical control box 1 through the electrical control box heat dissipation holes 5, which may prevents rainwater or water droplets from further entering the electrical control box 1.

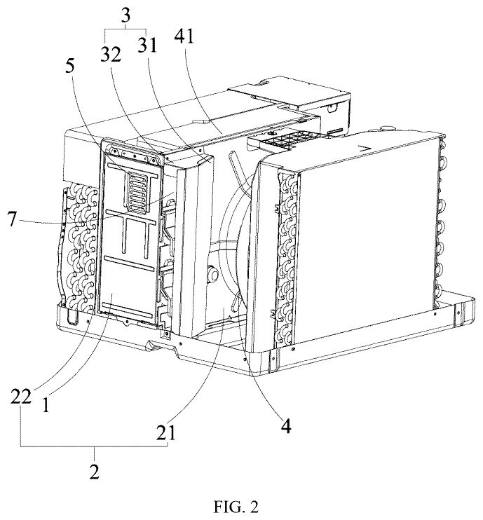

With continued reference to FIGS. 2, 3, 4, 6 and 7, the electrical control box 1 includes an electrical control box body 11 and an electrical control box cover 12. It may be understood that the purpose of assembling the electrical control box 1 from the electrical control box body 11 and the electrical control box cover 12 is to facilitate the maintenance and replacement of the internal components of the electrical control box 1. Certainly, the electrical control box 1 may also be of an integral design. The enclosing panel 2 includes a front enclosing panel 21 and a lateral enclosing panel 22, which are connected together to form an L-shape connection. The lateral enclosing panel 22 is provided with an electrical control box accommodation opening for receiving the electrical control box body 11 and a plurality of electrical control box mounting holes arranged around the electrical control box accommodation opening. Connection holes corresponding to the electrical control box mounting holes are arranged on the electrical control box body 11 and/or the electrical control box cover 12.

In some embodiments, the electrical control box body 11 is inserted into the electrical control box accommodation opening in a direction from a side of the lateral enclosing panel 22 away from the front enclosing panel 21 to a side of the lateral enclosing panel 22 facing the front enclosing panel 21. The connection holes on the electrical control box body 11 are connected to the electrical control box mounting holes on the lateral enclosing panel 22 by screws. The electrical control box cover 12 is installed on and covers the electrical control box body 11 on a side of the lateral enclosing panel 22 away from the front enclosing panel 21. Further, the connection holes on the electrical control box cover 12 may also be connected to the electrical control box mounting holes on the lateral enclosing panel 22 by screws. The advantage of this installation method is that when the internal components of the electrical control box 1 need to be maintained and replaced, only the cover needs to be opened to carry out maintenance and replacement, and there is no need to remove the lateral enclosing panel 22.

In some embodiments, the electrical control box body 11 is installed on the electrical control box cover 12, and the electrical control box cover 12 is connected to the lateral enclosing panel 22 through the electrical control box mounting holes. The advantage of this installation method is that it is convenient to remove and replace the entire electrical control box 1. In some embodiments, the lateral enclosing panel 22 may also not have any mounting holes. The electrical control box 1 or the electrical control box 11 is directly installed on the lateral enclosing panel 22. Alternatively, the electrical control box 1 is directly connected to the front enclosing panel 21. It is to be noted that, in some embodiments, at one end of the front enclosing panel 21 away from the lateral enclosing panel 22 (i.e., the end away from the electrical control box 1), there is also a fixed lateral enclosing panel connected to the front enclosing panel 21 in an L-shape. The fixed lateral enclosing panel is used to connect the front enclosing panel 21 and will be connected to the air conditioner to strengthen the stability of the enclosing panel 2.

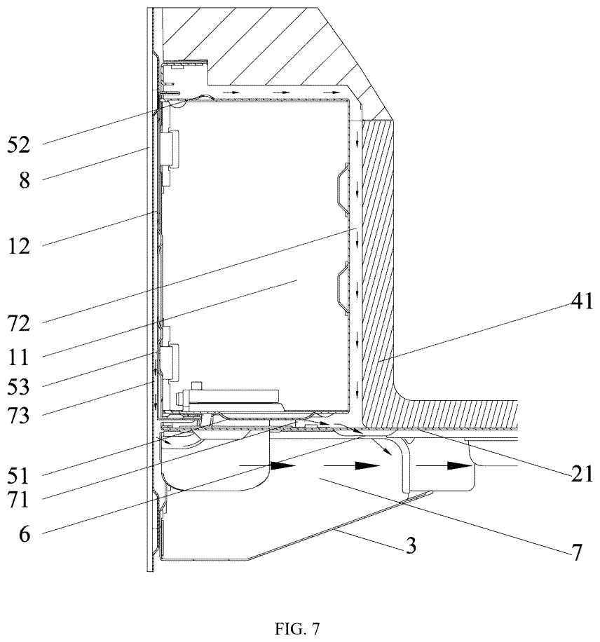

In some embodiments, referring to FIG. 7, the electrical control box heat dissipation holes 5 include first heat dissipation holes 51 arranged on a side wall of the electrical control box body 11 close to the front enclosing panel 21. The first heat dissipation holes 51 are arranged in a staggered manner with respect to the enclosing panel heat dissipation holes 6. A gap is reserved between the electrical control box body 11 and the front enclosing panel 21 and connects the first heat dissipation holes 51 to the enclosing panel heat dissipation holes 6, such that a first heat dissipation passage 71 is formed. The first heat dissipation passage 71 is in communication with the heat dissipation channel 7 through the enclosing panel heat dissipation holes 6. During operation, the air inside the electrical control box 1 heated by the internal components of the electrical control box 1 realizes convective heat exchange with the air in the first heat dissipation passage 71 through the first heat dissipation holes 51. Then, a convective heat exchange between the air inside the electrical control box 1 and the air in the heat dissipation channel 7 is realized through the enclosing panel heat dissipation holes 6. The efficiency of heat dissipation from the electrical control box 1 is improved through direct thermal air convection. In addition, arranging the first heat dissipation holes 51 and the enclosing panel heat dissipation holes 6 in a staggered manner helps to improve the waterproof performance of the electrical control box 1. In the most unfavorable situation, when outdoor rainwater or water droplets enter the area around the electrical control box 1 enclosed by the enclosing panel 2 through the enclosing panel heat dissipation holes 6, the staggered arrangement may prevent rainwater or water droplets from directly entering the electrical control box 1 through the first heat dissipation holes 51, avoiding damage to the internal components of the electrical control box 1 by water droplets when the above-mentioned situation occurs. It should be noted that the arrangement of the first heat dissipation passage 71 helps to dissipate the heat inside the electrical control box 1 on the one hand, and on the other hand, it may prevent the side wall of the electrical control box body 11 close to the front enclosing panel 21 from directly contacting the front enclosing panel 21, thereby avoiding water retention caused by capillary action.

With continued reference to FIGS. 2, 6 and 7, in some embodiments, the air conditioner includes an air duct volute 41 located on a side of the front enclosing panel 21 facing the electrical control box 1, where a gap is reserved between the electrical control box body 11 and the air duct volute 41 in a direction of a side of the electrical control box body 11 away from the front enclosing panel 21 and in a direction of a side of the electrical control box body 11 away from the electrical control box cover 12, such that a second heat dissipation passage 72 is formed. Correspondingly, the electrical control box heat dissipation holes 5 further include second heat dissipation holes 52 arranged on a side wall of the electrical control box body 11 away from the front enclosing panel 21. The second heat dissipation holes 52 are in communication with the enclosing panel heat dissipation holes 6 through the second heat dissipation passage 72, and the enclosing panel heat dissipation holes 6 are arranged directly opposite the second heat dissipation passage 72. It may be understood that the function of the second heat dissipation holes 52 is to exchange the air inside the electrical control box 1 with the air in the second heat dissipation passage 72, realizing convective heat exchange between the air inside the electrical control box 1 and the air in the second heat dissipation passage 72, and further enhancing the heat dissipation effect of the electrical control box 1. The beneficial effect of arranging the enclosing panel heat dissipation holes 6 directly opposite the second heat dissipation passage 72 lies in that on the one hand, it improves the efficiency of convective heat exchange between the air in the second heat dissipation passage 72 and the air in the heat dissipation channel 7, and on the other hand, it avoids the direct impact on the electrical control box 1 by outdoor rainwater or water droplets after they pass through the enclosing panel heat dissipation holes 6 in the most unfavorable situation.

In some embodiments, since the side of the electrical control box body 11 away from the front enclosing panel 21 is less likely to be invaded by water droplets, a heat vent 54 is provided on the side of the electrical control box body 11 away from the front enclosing panel 21. The heat vent is located at a lower part of the electrical control box body 11, and the second heat dissipation holes 52 are located at an upper part of the electrical control box body 11. That is to say, according to the actual working situation, under the condition of meeting the waterproof performance requirements or index requirements, heat vents of other shapes and quantities may also be added to the electrical control box body, and the present disclosure does not impose any restriction on this.

With continued reference to FIGS. 1 and 6, in some embodiments, the air conditioner includes an air conditioner outer housing 8. The electrical control box 1, the enclosing panel 2, the water baffle 3 and the fan 4 are all located inside the air conditioner outer housing 8. An air intake passage 9 is formed between the air conditioner outer housing 8 and the fan 4, and the water baffle 3 is arranged directly opposite the air intake passage 9. Refer to FIG. 1, the shown arrows indicate the air inlet and outlet directions. It may be understood that the air conditioner outer housing 8 substantially houses and encloses the air conditioner, rainwater or water droplets may only affect the electrical control box 1 through the air intake passage 9. Therefore, the purpose of arranging the water baffle 3 directly opposite the air intake passage 9 is to block the rainwater or water droplets coming from this path.

Referring to FIG. 2, the water baffle 3 includes a water baffling member 31 directly opposite the air intake passage 9 and upper and lower connection members 32 (i.e., an upper connection member and a lower connection member) connected to the water baffling member 31 at a predetermined angle. The water baffle 3 is connected to the front enclosing panel 21 through the upper and lower connection members 32. By setting the upper and lower connection members 32, the protection of the enclosing panel heat dissipation holes 6 in the vertical direction by the water baffle 3 is realized, and the waterproof performance of the electrical control box 1 is further improved.

In some embodiments, one side surface of the water baffle 3 close to the air conditioner outer housing 8 is compressively sealed to the air conditioner outer housing 8 through a flexible connection. For example, a flexible material such as a sealing rubber gasket is provided at the position where the water baffle 3 and the air conditioner outer housing 8 are compressed and sealed to achieve the compressive sealing. The water baffle 3 is provided with a heat dissipation opening on a side close to the fan 4 so that the heat dissipation channel 7 is in communication with the heat dissipation area. It may be understood that the beneficial effect of compressively sealing one side surface of the water baffle 3 close to the air conditioner outer housing 8 against the air conditioner outer housing 8 through a flexible connection lies in that through the compressive sealing between the water baffle 3 and the air conditioner outer housing 8, a complete partition wall is formed in the direction of the water baffle 3 directly opposite the air intake passage 9, which may effectively block the rainwater blown or sucked in from the air intake passage 9 from entering the heat dissipation channel 7 through the gap between the water baffle 3 and the air conditioner outer housing 8 and then entering the electrical control box 1. On the other hand, the function of providing a heat dissipation opening on the side of the water baffle 3 close to the fan 4 is to connect the heat dissipation channel 7 to the heat dissipation area, so that the hot air in the heat dissipation channel 7 may be directly dissipated outside by the fan 4 through the heat dissipation area. The shape and position of the heat dissipation opening may be adaptively set according to the working conditions of the device, and the present disclosure does not make specific limitations. In an embodiment, the heat dissipation opening is provided on the water baffle 3 at a height equivalent to or higher than the height of the enclosing panel heat dissipation holes 6.

Since the fan 4 needs to suck in air from the air intake passage 9 during operation, based on the air movement trajectory inside the air intake passage 9, in some embodiments, referring to FIG. 2, the water baffling member 31 is bent on a side close to the fan 4 towards the front enclosing panel 21 at a predetermined angle, the enclosing panel heat dissipation holes 6 are arranged at an upper part of the front enclosing panel 21, the water baffling member 31 narrows in a direction away from the fan 4 at a position lower than a predetermined height of a lower edge of the enclosing panel heat dissipation holes 6.

It should be noted that the advantage of bending the water baffling member 31 towards the front enclosing panel 21 at a predetermined angle on the side close to the fan 4 lies in that in one aspect, it improves the air intake efficiency of the air intake passage 9, thereby improving the working efficiency and heat exchange efficiency of the fan; in another aspect, it reduces the probability of rainwater or water droplets entering the heat dissipation channel 7; and in yet another aspect, by bending the water baffling member 31 on the side close to the fan 4 towards the front enclosing panel 21 at a predetermined angle, the movement speed of the hot air at the heat dissipation opening of the heat dissipation channel 7 is increased. Using the Bernoulli effect, the dissipation rate of the hot air in the heat dissipation channel 7 may be greatly accelerated. The beneficial effect of providing the enclosing panel heat dissipation holes 6 at the upper part of the front enclosing panel 21 lies in that on the one hand, it may effectively accelerate the dissipation of the hot air in the first heat dissipation passage 71 and the second heat dissipation passage 72 by utilizing the characteristic of the upward movement of hot air; and on the other hand, setting the holes higher may prevent rainwater from entering the first heat dissipation passage 71 and the second heat dissipation passage 72 through the enclosing panel heat dissipation holes 6 in extreme weather. At the same time, the purpose of narrowing the water baffling member 31 in the direction away from the fan 4 at a position lower than a predetermined height of the lower edge of the enclosing panel heat dissipation holes 6 is that on the premise of ensuring that the hot air emitted from the enclosing panel heat dissipation holes 6 is further dissipated through the heat dissipation channel 7, the air intake efficiency and air intake speed of the air intake passage 9 are improved, thereby improving the heat dissipation efficiency of the fan 4, and by using the Bernoulli effect, the dissipation rate of the hot air in the heat dissipation channel 7 is further accelerated.

Certainly, according to the actual working conditions and requirements of the device, the bending angle of the water baffling member 31 on the side close to the fan 4 towards the front enclosing panel 21, the height at which the enclosing panel heat dissipation holes 6 are provided on the front enclosing panel 21, the height at which the water baffling member 31 is narrowed and the narrowing scale of the water baffling member 31 may be adaptively adjusted, and the present disclosure does not impose any restrictions on these.

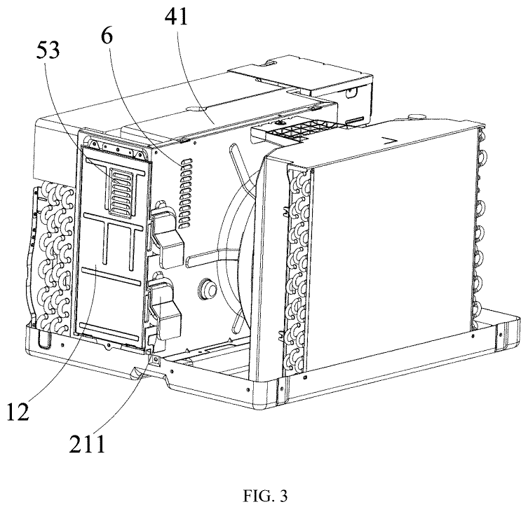

With continued reference to FIGS. 3, 6 and 7, in some embodiments, a gap is reserved between the air conditioner outer housing 8 and the electrical control box cover 12 to form a third heat dissipation passage 73. The third heat dissipation passage 73 is in communication with the heat dissipation channel 7. The electrical control box heat dissipation holes 5 further include third heat dissipation holes 53 arranged on the electrical control box cover 12, and the third heat dissipation holes 53 are in communication with the heat dissipation channel 7 through the third heat dissipation passage 73. It may be understood that the function of the third heat dissipation holes 53 is to exchange the air inside the electrical control box 1 with the air in the third heat dissipation passage 73, realizing convective heat exchange between the air inside the electrical control box 1 and the air in the third heat dissipation passage 73. Then, the hot air after heat exchange is dissipated through the heat dissipation channel 7 formed between the water baffle 3 and the front enclosing panel 21, further enhancing the heat dissipation effect of the electrical control box 1.

Both the electrical control box heat dissipation holes 5 and the enclosing panel heat dissipation holes 6 are louvered heat dissipation holes. The electrical control box heat dissipation holes 5 are inclined downward in the direction from the inner side of the electrical control box 1 to the outer side of the electrical control box 1. The enclosing panel heat dissipation holes 6 are inclined downward in the direction from the side facing the electrical control box 1 to the side away from the electrical control box 1 of the enclosing panel 2. It may be understood that the advantage of setting the electrical control box heat dissipation holes 5 as louvered heat dissipation holes and inclining them downward lies in preventing rainwater or water droplets from entering the electrical control box 1 from the upper side. The purpose of setting the enclosing panel heat dissipation holes 6 as louvered heat dissipation holes and inclining them downward is to prevent rainwater or water droplets from entering the first heat dissipation passage 71 and the second heat dissipation passage 72 from the upper side. The shapes and orientations of the electrical control box heat dissipation holes 5 and the enclosing panel heat dissipation holes 6 may be adaptively adjusted according to the working conditions and actual needs of the device, and the present disclosure does not impose any restrictions on these.

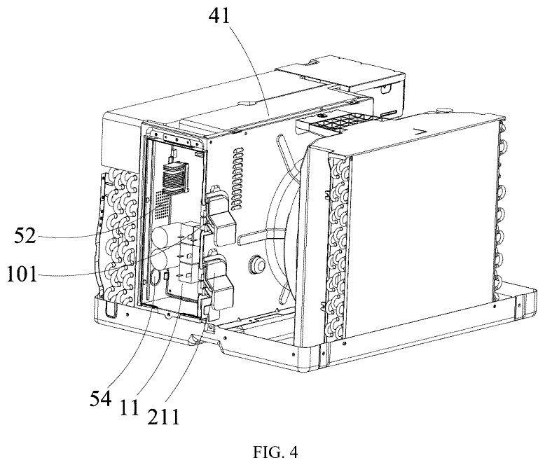

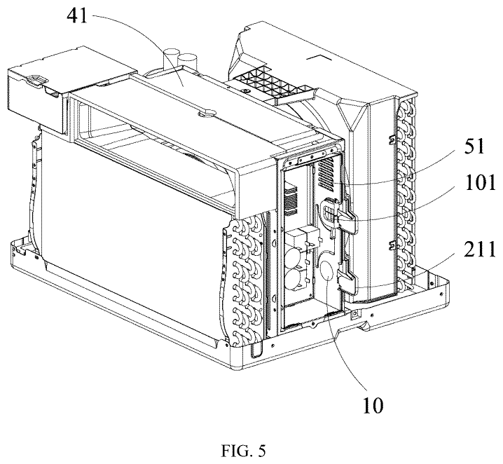

With continued reference to FIGS. 4 and 5, in some embodiments, a cable passage hole 10 is arranged on a side of the electrical control box body 11 close to the front enclosing panel 21. A sealing rubber block 101 is arranged at the cable passage hole 10, and a waterproof cable-pressing cover plate 211 is arranged on the front enclosing panel 21 at a position opposite the cable passage hole 10. The sealing rubber block 101 and the waterproof cable-pressing cover plate 211 are both arranged facing downward. It may be understood that the purpose of providing the sealing rubber block 101 at the cable passage hole 10, providing the waterproof cable-pressing cover plate 211 at the position on the front enclosing panel 21 directly opposite the cable passage hole 10, and arranging both the sealing rubber block 101 and the waterproof cable-pressing cover plate 211 facing downward is to ensure the waterproof performance requirements of the electrical control box 1 while fulfilling the wiring requirements. Any other waterproof measures and technical means that meet the waterproof requirements may also be adopted at the cable passage hole 10, and the present disclosure does not make specific limitations.

When the air conditioner is working, the internal components of the electrical control box 1 will heat the air inside the electrical control box 1. Part of the hot air inside the electrical control box 1 enters the first heat dissipation passage 71 through the first heat dissipation holes 51, part of the hot air enters the second heat dissipation passage 72 through the second heat dissipation holes 52 and the heat vent 54, and part of the hot air enters the third heat dissipation passage 73 through the third heat dissipation holes 53 and then enters the heat dissipation channel 7. The hot air in the first heat dissipation passage 71 and the second heat dissipation passage 72 enters the heat dissipation channel 7 through the enclosing panel heat dissipation holes 6. The hot air in the heat dissipation channel 7 passes through the heat dissipation opening on the water baffle 3 and is then dissipated outside the air conditioner by the fan 4 through the negative-pressure heat dissipation area generated by the operation of the fan 4. The rainwater or water droplets entering from the direction of the air intake passage 9 are directly blocked by the water baffle 3 on the side of the water baffle 3 away from the enclosing panel heat dissipation holes 6, thus avoiding the influence of rainwater or water droplets on the electrical control box 1. Thus, the electrical control box 1 can simultaneously meet the performance requirements of waterproofing and heat dissipation.

It should be noted that the relative terms herein, such as “first” and “second” are used only to distinguish one entity or operation from another entity or operation, without necessarily requiring or implying any such actual relationship or sequence between these entities or operations. In addition, the terms “comprise,” “include” or any variation thereof are intended to cover a non-exclusive inclusion, such that a process, method, article, or device that includes a series of elements not only includes those listed elements but also includes other elements not expressly listed or further includes elements inherent to such a process, method, article, or device. An element preceded by “comprising/including a/an” does not, without more constraints, preclude the existence of additional identical elements in the process, method, article, or apparatus that comprises/includes the element.

The above description illustrates merely specific implementations of the present disclosure, so that a person skilled in the art can understand or implement the present disclosure. Various modifications to these embodiments are apparent to those skilled in the art, and the general principle defined herein may be practiced in other embodiments without departing from the scope of the present disclosure. Therefore, the present disclosure is not limited to the embodiments described herein but is to be accorded with the broadest scope consistent with the principle and novel features disclosed herein.

1-13. (canceled)

14. An air conditioner comprising:
an enclosing panel, provided with enclosing panel heat dissipation holes;
an electrical control box, connected to the enclosing panel and provided with electrical control box heat dissipation holes;
a water baffle, arranged on a side of the enclosing panel away from the electrical control box and corresponding to a position of the enclosing panel heat dissipation holes, a heat dissipation channel being formed between the water baffle and the enclosing panel; and
a fan, arranged on the side of the enclosing panel away from the electrical control box, a heat dissipation area being formed between a side of the fan facing the enclosing panel and the enclosing panel, and a heat dissipation port of the heat dissipation channel being in communication with the heat dissipation area.

15. The air conditioner of claim 14, wherein,
on a projection plane perpendicular to the enclosing panel, projections of the electrical control box heat dissipation holes are spaced apart from projections of the enclosing panel heat dissipation holes.

16. The air conditioner of claim 15, wherein:
the electrical control box includes an electrical control box body and an electrical control box cover,
the enclosing panel includes a front enclosing panel and a lateral enclosing panel, and the front enclosing panel and the lateral enclosing panel are connected together to form an L-shape connection;
the lateral enclosing panel is provided with an electrical control box accommodation opening for receiving the electrical control box body and a plurality of electrical control box mounting holes arranged around the electrical control box accommodation opening; and
at least one of the electrical control box body or the electrical control box cover is provided with connection holes corresponding to the electrical control box mounting holes.

17. The air conditioner of claim 16, wherein:
the electrical control box heat dissipation holes include heat dissipation holes arranged on a side wall of the electrical control box body close to the front enclosing panel and arranged in a staggered manner with respect to the enclosing panel heat dissipation holes; and
a gap between the electrical control box body and the front enclosing panel connects the heat dissipation holes to the enclosing panel heat dissipation holes to form a heat dissipation passage that is in communication with the heat dissipation channel through the enclosing panel heat dissipation holes.

18. The air conditioner of claim 17, further comprising:
an air duct volute located on a side of the front enclosing panel facing the electrical control box;
wherein:
the heat dissipation holes are first heat dissipation holes, and the heat dissipation passage is a first heat dissipation passage;
a gap between the electrical control box body and the air duct volute in a direction of a side of the electrical control box body away from the front enclosing panel and in a direction of a side of the electrical control box body away from the electrical control box cover forms a second heat dissipation passage;
the electrical control box heat dissipation holes further include second heat dissipation holes arranged on a side wall of the electrical control box body away from the front enclosing panel, the second heat dissipation holes being in communication with the enclosing panel heat dissipation holes through the second heat dissipation passage; and
the enclosing panel heat dissipation holes are arranged directly opposite the second heat dissipation passage.

19. The air conditioner of claim 18, wherein:
a heat vent is arranged on a side of the electrical control box body away from the front enclosing panel; and
the heat vent is located at a lower part of the electrical control box body, and the second heat dissipation holes are located at an upper part of the electrical control box body.

20. The air conditioner of claim 16, further comprising:
an air conditioner outer housing;
wherein:
the electrical control box, the enclosing panel, the water baffle, and the fan are all located inside the air conditioner outer housing; and
an air intake passage is formed between the air conditioner outer housing and the fan, and the water baffle is arranged directly opposite the air intake passage.

21. The air conditioner of claim 20, wherein:
the water baffle includes a water baffling member opposite the air intake passage and upper and lower connection members connected to the water baffling member at a predetermined angle; and
the water baffle is connected to the front enclosing panel via the upper and lower connection members.

22. The air conditioner of claim 21, wherein:
a side surface of the water baffle close to the air conditioner outer housing is compressively sealed to the air conditioner outer housing through a flexible connection; and
a heat dissipation opening is arranged on a side of the water baffle close to the fan such that the heat dissipation channel is in communication with the heat dissipation area.

23. The air conditioner of claim 21, wherein:
the water baffling member is bent on a side close to the fan towards the front enclosing panel at a predetermined angle;
the enclosing panel heat dissipation holes are arranged at an upper part of the front enclosing panel;
the water baffling member narrows in a direction away from the fan at a position below a predetermined height of a lower edge of the enclosing panel heat dissipation holes.

24. The air conditioner of claim 20, wherein:
a gap between the air conditioner outer housing and the electrical control box cover forms a heat dissipation passage that is in communication with the heat dissipation channel;
the electrical control box heat dissipation holes include heat dissipation holes arranged on the electrical control box cover and in communication with the heat dissipation channel through the heat dissipation passage.

25. The air conditioner of claim 20, wherein:
both the electrical control box heat dissipation holes and the enclosing panel heat dissipation holes are louvered heat dissipation holes;
the electrical control box heat dissipation holes are inclined downward in a direction from an inner side of the electrical control box to an outer side of the electrical control box; and
the enclosing panel heat dissipation holes are inclined downward in a direction from a side facing the electrical control box to a side away from the electrical control box of the enclosing panel.

26. The air conditioner of claim 20, wherein:
a cable passage hole is arranged on a side of the electrical control box body close to the front enclosing panel;
a sealing rubber block is arranged at the cable passage hole; and
a waterproof cable-pressing cover plate is arranged on the front enclosing panel at a position opposite the cable passage hole.
